(19) United States
(12) Patent Application Publication
(10) Pub. No.: US 2019/0140210 A1
(43) Pub. Date: May 9, 2019

(54) PROTECTIVE STRUCTURE AND ELECTRONIC DEVICE

(71) Applicants: Industrial Technology Research Institute, Hsinchu (TW); Intellectual Property Innovation Corporation, Hsinchu (TW)

(72) Inventors: Ting-Hsun Cheng, Chiayi County (TW); Chih-Chia Chang, Hsinchu County (TW); Kai-Ming Chang, New Taipei City (TW); Jui-Chang Chuang, Kaohsiung City (TW)

(73) Assignees: Industrial Technology Research Institute, Hsinchu (TW); Intellectual Property Innovation Corporation, Hsinchu (TW)

(21) Appl. No.: 15/856,059

(22) Filed: Dec. 28, 2017

(30) Foreign Application Priority Data
Nov. 7, 2017 (TW) 106138523

(51) Int. Cl. H01L 51/52

(52) U.S. Cl. CPC H01L 51/5253; H01L 51/0097; H01L 51/5281

(57) ABSTRACT

A protective structure includes a substrate, a hard coating layer and an auxiliary layer. The auxiliary layer is disposed on the substrate. The hard coating layer is disposed on the auxiliary layer. The auxiliary layer is disposed between the substrate and the hard coating layer. The Young's modulus of the auxiliary layer is greater than the Young's modulus of the hard coating layer, and the Young's modulus of the hard coating layer is greater than the Young's modulus of the substrate.

### CROSS-REFERENCE TO RELATED APPLICATION

This application claims the priority benefit of Taiwan application serial no. 106138523, filed on Nov. 7, 2017. The entirety of the above-mentioned patent application is hereby incorporated by reference herein and made a part of this specification.

### BACKGROUND

### Technical Field

The disclosure relates to a protective structure and an electronic device.

### Description of Related Art

An electronic component (e.g., flexible electronic component) may have less mechanical strength and hardness after being lighter and thinner, and consequently may be easily damaged when scratched, or worn by an external force during the manufacturing process, delivery, or use, which impairs the reliability of the device.

When a hard coating layer is disposed on the surface of the electronic component, the scratch resistance of the electronic component may be increased. However, the material of the component is easily cracked after being folded when the thickness of the hard coating layer is increased, even though the scratch resistance of the electronic component may be improved.

### SUMMARY

According to an embodiment of the disclosure, a protective structure is provided. The protective structure includes a substrate, a hard coating layer and an auxiliary layer. The auxiliary layer is disposed on the substrate. The hard coating layer is disposed on the auxiliary layer. The auxiliary layer is disposed between the substrate and the hard coating layer. The Young's modulus of the auxiliary layer is greater than the Young's modulus of the hard coating layer, and the Young's modulus of the hard coating layer is greater than the Young's modulus of the substrate.

According to an embodiment of the disclosure, a protective structure is provided. The protective structure is useful for an electronic component and includes a hard coating layer and an auxiliary layer. The hard coating layer is disposed on the electronic component. The auxiliary layer is disposed between the electronic component and the hard coating layer. The Young's modulus of the auxiliary layer is greater than the Young's modulus of the hard coating layer.

According to yet another embodiment of the disclosure, an electronic device is provided. The electronic device includes an electronic component and the protective structure located on the electronic component. The protection structure includes at least a hard coating layer and an auxiliary layer. The auxiliary layer is disposed between the electronic component and the hard coating layer. The Young's modulus of the auxiliary layer is greater than the Young's modulus of the hard coating layer.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic cross-sectional view of a protective structure that includes a substrate according to an embodiment of the disclosure.

FIG. 1B is a schematic cross-sectional view of a protective structure that includes a substrate according to another embodiment of the disclosure.

FIG. 1C is a schematic cross-sectional view of a protective structure that includes a substrate according to yet another embodiment of the disclosure.

FIG. 1D is a schematic cross-sectional view of an electronic device according to an embodiment of the disclosure.

FIG. 1E is a schematic cross-sectional view of an electronic device according to another embodiment of the disclosure.

FIG. 1F is a schematic cross-sectional view of an electronic device according to yet another embodiment of the disclosure.

FIG. 2A to FIG. 2B are schematic cross-sectional views of a non-continuous surface structures of the auxiliary layers according to embodiments of the disclosure.

FIG. 2C-1 to FIG. 2C-3 are top views of three exemplary non-continuous surface structures of the auxiliary layers shown in FIG. 2A to FIG. 2B.

FIG. 3A is a schematic cross-sectional view of a protective structure according to another embodiment of the disclosure.

FIG. 3B is a schematic cross-sectional view of a protective structure according to another embodiment of the disclosure.

FIG. 3C is a schematic cross-sectional view of an electronic device according to another embodiment of the disclosure.

FIG. 3D is a schematic cross-sectional view of an electronic device according to another embodiment of the disclosure.

FIG. 4 is a schematic cross-sectional view of a protective structure according to another embodiment of the disclosure.

FIG. 5A to FIG. 5C are top views of three exemplary patterned auxiliary layers according to embodiments of the disclosure.

FIG. 6A is a schematic cross-sectional view of a protective structure according to another embodiment of the disclosure.

FIG. 6B is a schematic cross-sectional view of a protective structure according to another embodiment of the disclosure.

FIG. 6C is a schematic cross-sectional view of a protective structure according to another embodiment of the disclosure.

FIG. 7 is a schematic cross-sectional view of a protective structure according to another embodiment of the disclosure.

FIG. 8 is a schematic cross-sectional view of a protective structure according to another embodiment of the disclosure.

FIG. 9 is a schematic cross-sectional view of a protective structure according to another embodiment of the disclosure.

FIG. 10 is a schematic cross-sectional view of a protective structure according to another embodiment of the disclosure.

FIG. 11 is a schematic cross-sectional view of a protective structure according to another embodiment of the disclosure.

FIG. 12 is a schematic cross-sectional view of a protective structure according to another embodiment of the disclosure.

FIG. 13 is a diagram showing the simulation results of the different protective structures under the maximum normal stress.

### DESCRIPTION OF THE EMBODIMENTS

The following disclosure of the specification provides different embodiments, or examples, for implementing different features of various embodiments. Specific examples of respective components and arrangements are described below to simplify the present disclosure. These are, of course, merely examples and are not intended to be limiting. In addition, the disclosure may repeat reference numerals and/or letters in the various examples. This repetition is for the purpose of simplicity and clarity and does not in itself dictate a relationship between the various embodiments and/or configurations discussed. Moreover, the formation of a first feature above or on a second feature in the description that follows may include embodiments in which the first and second features are formed in direct contact, and may also include embodiments in which additional features may be formed interposing the first and second features, such that the first and second features may not be in direct contact. The sizes or proportions of the elements described in the drawings are merely provided for the convenience of explanations, and should not be used to represent the actual sizes or proportions of the elements.

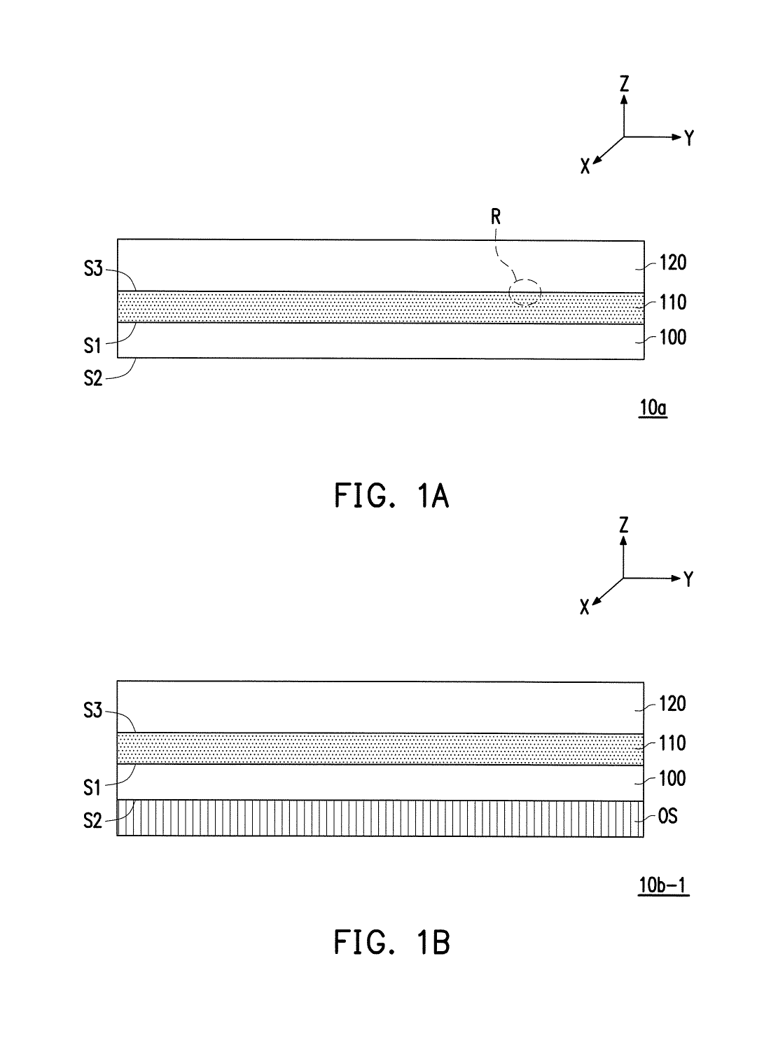

FIG. 1A is a schematic cross-sectional view of a protective structure 10a that includes a substrate 100 according to an embodiment of the disclosure. Referring to FIG. 1A, the protective structure 10a includes the substrate 100, an auxiliary layer 110 and a hard coating layer 120. The auxiliary layer 110 may be an anti-scratch auxiliary layer with the scratch resistance. The substrate 100 has a first surface S1 and a second surface S2 opposite to the first surface S1. The auxiliary layer 110 is disposed on the first surface S1 of the substrate 100. The hard coating layer 120 is disposed on the first surface S1 of the substrate 100, and the auxiliary layer 110 is disposed between the substrate 100 and the hard coating layer 120. The auxiliary layer 110 and the hard coating layer 120 may be unpatterned layers respectively. In other words, the auxiliary layer 110 covers the first surface S1 of the substrate 100 completely, and the hard coating layer 120 covers the auxiliary layer 110 completely.

In an embodiment, the substrate 100 may be a single-material substrate such an organic material or an inorganic material. The organic material includes polyimide (PI), poly(methyl methacrylate) (PMMA), polycarbonate (PC), polyethersulfone (PES), polyamide (PA), polyethylene terephthalate (PET), poly(ether ether ketone) (PEEK), polyethylene naphthalate (PEN), polyethylenimine (PEI), polyurethane (PU), polydimethylsiloxane (PDMS), acrylic, polyvinylidene fluoride (PVDF), polyvinyl alcohol (PVA), a polymer containing ether, polyolefin, or the like, or a combination of the foregoing, but not limited thereto. The inorganic material includes single metal, metal oxide, non-metal oxide, non-metal nitride, ceramic, or the like, or a composite material composed of the foregoing, but not limited thereto. The inorganic material is, for example, diamond-like carbon (DLC), silicon nitride, silicon oxide, silicon oxynitride, aluminum oxide, aluminum titanium dioxide, titanium oxide, titanium oxynitride, solution gas barrier (SGB) such as polysilazane, or the like. In an embodiment, the substrate 100 may be a composite substrate including an organic material and an inorganic material. The composite substrate including an organic material and an inorganic material refers to a substrate formed by mixing the organic material and the inorganic material.

In an embodiment, the auxiliary layer 110 may be an inorganic material, an organic material, or a composite material composed of an organic material and an inorganic material. The inorganic material includes single metal, metal oxide, non-metal oxide, non-metal nitride, ceramic, or the like, or a composite material composed of the foregoing, but not limited thereto. The inorganic material is, for example, diamond-like carbon (DLC), silicon nitride, silicon oxide, silicon oxynitride, aluminum oxide, aluminum titanium dioxide, sapphire coating, titanium oxynitride, or solution gas barrier (SGB) such as polysilazane. The organic material includes pentaerythritol tri(meth)acrylate, an acrylate, a resin, a polymer, a photoresist, or the like, or a composite material composed of the foregoing, but not limited thereto. In an embodiment, the inorganic material may be a powder material having a particle size of less than 100 nanometers. Taking the diamond-like carbon as an example, a third surface S3 of the auxiliary layer 110 which is away from the substrate 100 and formed by the diamond-like carbon may be a continuous surface structure or a non-continuous surface structure. The continuous surface structure means that the third surface S3 (X-Y plane) is a flat surface. The non-continuous surface structure means that the third surface S3 (X-Y plane) is a bump and groove surface (or referred as a concave and convex surface). The non-continuous surface structure may be formed by a manufacturing method such as sputtering. The surface of the non-continuous surface structure has micro gap which has the width smaller than 1 μm.

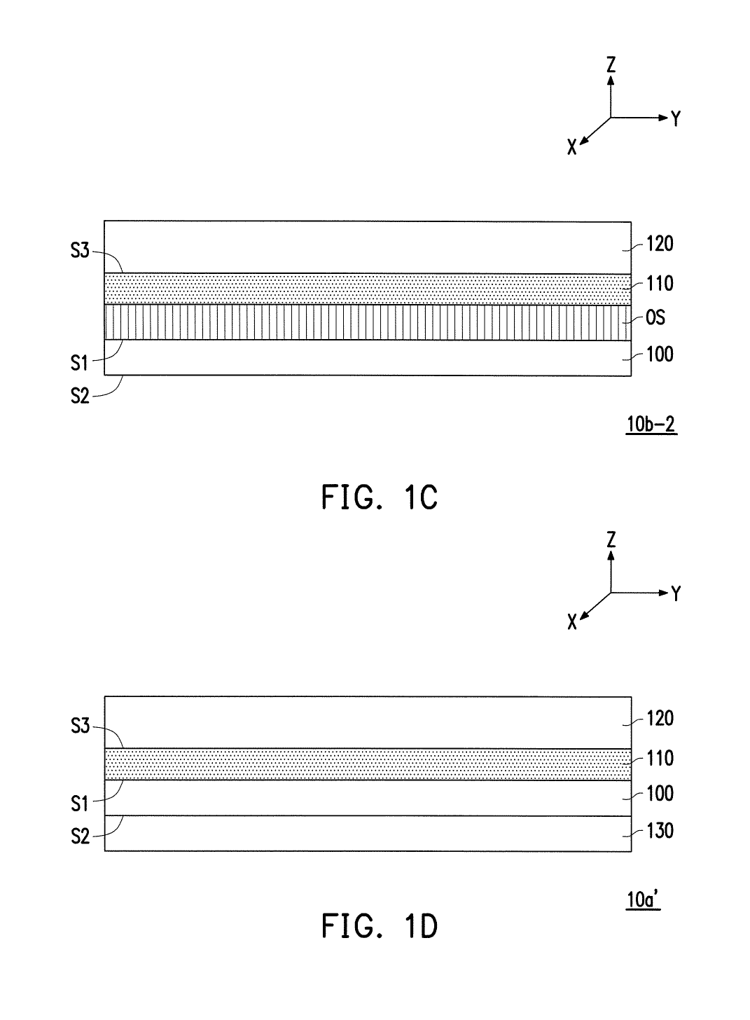

Referring to FIG. 2A to FIG. 2B, FIG. 2A to FIG. 2B which illustrate non-continuous surface structures of auxiliary layers are schematic cross-sectional views of auxiliary layers 110 according to embodiments of the disclosure. The non-continuous surface refers to the surface with a bump and groove structure (or referred as a concave and convex structure). With reference to the embodiment of FIG. 1A, FIG. 2A to FIG. 2B are enlarged views of the region R in FIG. 1A. FIG. 2A is a schematic cross-sectional view of the auxiliary layer 110 with a non-continuous surface structure according to an embodiment of the disclosure. FIG. 2B is a schematic cross-sectional view of the auxiliary layer 110 with a non-continuous surface structure according to another embodiment of the disclosure. Referring to FIG. 2A, the non-continuous surface structure of the auxiliary layer 110 is configured with a plurality of grooves cc on a plane p1 (X-Y plane) of the auxiliary layer 110. Referring to FIG. 2B, the non-continuous surface structure of the auxiliary layer 110 is configured with a plurality of bumps cv on a plane p1 (X-Y plane) of the auxiliary layer 110. The gap depth and the gap width are marked in FIG. 2A and FIG. 2B. The gap depth d1 is the distance between the plane p1 of the auxiliary layer 110 and the bottom of the grooves cc, or the distance between the plane p1 of the auxiliary layer 110 and the top of the bumps cv, wherein the gap depth may be 0.1˜0.8 μm; the gap width w is the distance between the two adjacent grooves cc of the auxiliary layer 110 or the distance between the two adjacent bumps cv, wherein the gap width is less than 1 μm, and is 0.1˜0.99 μm in an embodiment.

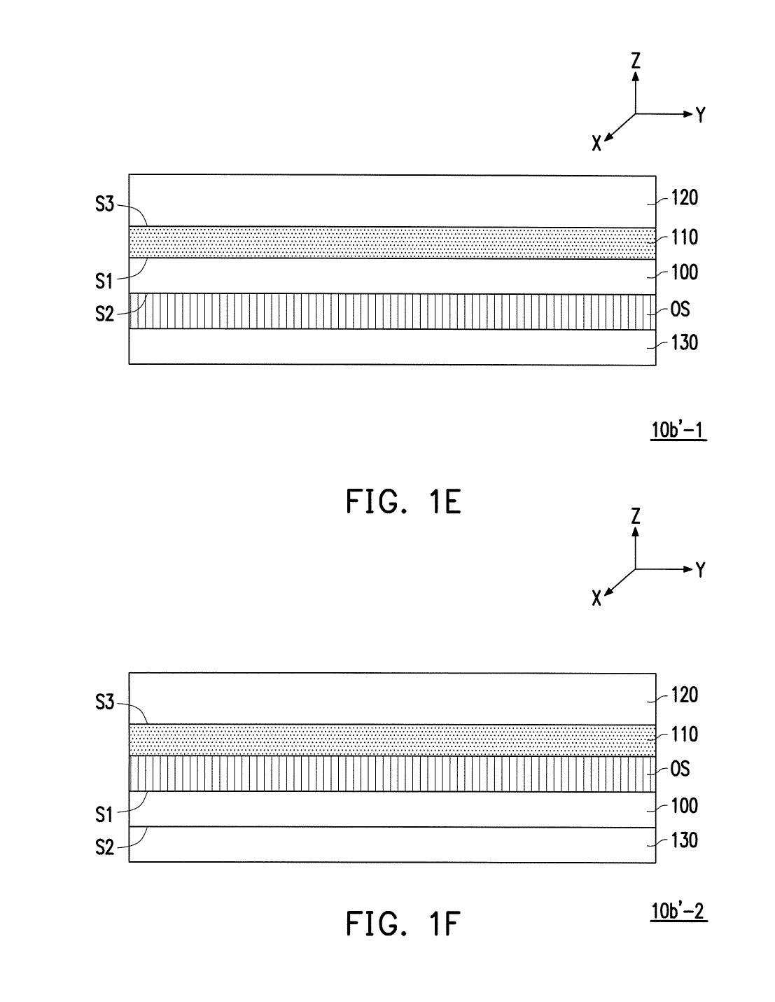

Referring to FIG. 2C-1 to FIG. 2C-3, and FIG. 2C-1 to FIG. 2C-3 are top views of the auxiliary layer 110 with the non-continuous surface structure of FIG. 2A to FIG. 2B. FIG. 2C-1 to FIG. 2C-3 show top views of three exemplary non-continuous surface structures. FIG. 2C-1 shows a surface with a bump and groove structure of ordered line segments. FIG. 2C-2 shows a surface with a bump and groove structure of ordered polygons. FIG. 2C-3 shows a surface with a disordered bump and groove structure. The surface structures are merely examples, and the disclosure is not limited thereto.

In an embodiment, the hard coating layer 120 includes pentaerythritol tri(meth)acrylate, acrylate, or the like, or a combination of the forgoing, but not limited thereto.

Referring to FIG. 1A again, the descending order of the Young's modulus of the substrate 100, the auxiliary layer 110, and the hard coating layer 120 of the protective structure 10a is the Young's modulus of the auxiliary layer 110, the Young's modulus of the hard coating layer 120, the Young's modulus of the substrate 100. The Young's modulus of the substrate 100 may be between 1 and 20 GPa (10⁹ Pa). The Young's modulus of the hard coating layer 120 may be between 10 and 30 GPa. Under conditions satisfying the order of the Young's modulus of the auxiliary layer 110, the Young's modulus of the hard coating layer 120, and the Young's modulus of the substrate 100, the Young's modulus of the material of the auxiliary layer 110 is, for example, at least equal to or greater than 15 GPa. In an embodiment, the Young's modulus of the material of the auxiliary layer 110 may be between 15 and 100 GPa, and the ratio of the Young's modulus of the auxiliary layer 110 to the Young's modulus of the hard coating layer 120 (i.e., the Young's modulus _{the auxiliary layer}/the Young's modulus _{the hard coating layer}) is greater than 1, and less than or equal to 10, and the ratio of the Young's modulus of the auxiliary layer 110 to the Young's modulus of the substrate 100 (i.e., the Young's modulus _{the auxiliary layer}/the Young's modulus _{the substrate}) is greater than 1, and less than or equal to 100. In another embodiment, the Young's modulus of the auxiliary layer 110 may be between 20 and 80 GPa, and the range of the ratio of the Young's modulus of the auxiliary layer 110 to the Young's modulus of the hard coating layer 120 is greater than 1, and less than or equal to 8, and the range of the ratio of the Young's modulus of the auxiliary layer 110 to the Young's modulus of the substrate 100 is greater than 1, and less than or equal to 80. In yet another embodiment, the Young's modulus of the auxiliary layer 110 may be between 40 and 60 GPa, and the range of the ratio of the Young's modulus of the auxiliary layer 110 to the Young's modulus of the hard coating layer 120 is 1.33 to 6, and the range of the ratio of the Young's modulus of the auxiliary layer 110 to the Young's modulus of the substrate 100 is 2 to 60.

Still referring to FIG. 1A, the thickness of the substrate 100 is between 5 and 50 μm in the protective structure 10a. The thickness of the hard coating layer 120 is between 5 and 35 μm, and the thickness of the auxiliary layer 110 is between 0.1 and 30 μm. The range of the ratio of the thickness of the auxiliary layer 110 to the thickness of the hard coating layer 120 (i.e., the thickness _{the auxiliary layer}/the thickness _{the hard coating layer}) is 0.003 to 6, and the range of the ratio of the thickness of the auxiliary layer 110 to the thickness of the substrate 100 (i.e., the thickness _{the auxiliary layer}/the thickness _{the substrate}) is 0.002 to 6. In an embodiment where the auxiliary layer 110 is made of an inorganic material, the thickness of the auxiliary layer 110 may be between 0.1 and 1 μm, and the range of the ratio of the thickness of the auxiliary layer 110 to the thickness of the hard coating layer 120 (i.e., the thickness _{the auxiliary layer}/the thickness _{the hard coating layer}) is 0.03 to 6, and the range of the ratio of the thickness of the auxiliary layer 110 to the thickness of the substrate 100 (i.e., the thickness _{the auxiliary layer}/the thickness _{the substrate}) is 0.02 to 6. In another embodiment where the auxiliary layer 110 is made of an organic material, the thickness of the auxiliary layer 110 may be between 1 and 30 μm, and the range of the ratio of the thickness of the auxiliary layer 110 to the thickness of the hard coating layer 120 (i.e., the thickness _{the auxiliary layer}/the thickness _{the hard coating layer}) is 0.003 to 0.16, and the range of the ratio of the thickness of the auxiliary layer 110 to the thickness of the substrate 100 (i.e., the thickness _{the auxiliary layer}/the thickness _{the substrate}) is 0.002 to 6.

Referring to FIG. 1A again, the auxiliary layer 110 and the hard coating layer 120 may be formed by any known method. The auxiliary layer made of an organic material may be formed by coating, printing, or the like. The auxiliary layer made of an inorganic material may be formed by a process such as sputtering, vapor deposition, chemical vapor deposition, physical vapor deposition, or the like. In an embodiment, the auxiliary layer 110 is formed on the substrate 110 by coating, printing, sputtering or chemical vapor deposition, or the like, and then the hard coating layer 120 is formed on the auxiliary layer 110 by coating.

FIG. 1B is a schematic cross-sectional view of a protective structure according to another embodiment of the disclosure, wherein the protective structure 10b-1 has a substrate 100 and an optical structure layer (OSL) OS. The optical structure layer OS may be a circular polarizer layer (CPL) or a light filter structure layer.

Referring to FIG. 1B, the protective structure 10b-1 is similar to the protective structure 10a in FIG. 1A, except that the protective structure 10b-1 further includes the optical structure layer OS, wherein the optical structure layer OS is disposed on a second surface S2 of the substrate 100, and the substrate 100 is disposed between the auxiliary layer 110 and the optical structure layer OS. The optical structure layer OS may be a circular polarizer layer (CPL) or a light filter structure layer. The circular polarizer layer is, for example, a polarizing layer and a phase retardation layer, wherein the polarizing layer may be a linear polarizing layer and the phase retardation layer may be a quarter-wave retarder plate. The light filter structure layer is, for example, a black filter layer, a color filter layer, or a combination of both. The Young's modulus of the optical structure layer OS may be between 1 and 20 GPa and the thickness may be between 0.5 and 20 μm. The optical structure layer OS may be adhered onto the substrate 100 through an adhesive or formed on the substrate 100 directly by wet coating or dry film-forming method.

FIG. 1C is a schematic cross-sectional view of a protective structure according to yet another embodiment of the disclosure, wherein the protective structure 10b-2 has a substrate 100 and an optical structure layer (OSL) OS.

Referring to FIG. 1C, the protective structure 10b-2 is similar to the protective structure 10b-1 in FIG. 1B, except that the optical structure layer OS of the protective structure 10b-2 is disposed on the first surface S1 of the substrate 100, and the optical structure layer OS is disposed between the substrate 100 and the auxiliary layer 110. The circular polarizer layer is, for example, a polarizing layer and a phase retardation layer, wherein the polarizing layer may be a linear polarizing layer and the phase retardation layer may be a quarter-wave retarder plate. The Young's modulus of the optical structure layer OS may be between 1 and 20 GPa and the thickness may be between 0.5 and 20 μm. The optical structure layer OS may be adhered onto the substrate 100 through an adhesive or formed on the substrate 100 directly by wet coating or dry film-forming method.

FIG. 1D is a schematic cross-sectional view of an electronic device according to an embodiment of the disclosure, wherein the electronic device 10a′ has a substrate 100.

Referring to FIG. 1D, in an embodiment, the electronic device 10a′ includes an electronic component 130 in addition to the protective structure 10a as shown in FIG. 1A. The electronic component 130 is disposed on the second surface S2 of the substrate 100, wherein the first surface S1 and the second surface S2 of the substrate 100 are opposite to each other. The protective structure 10a may be adhered to the electronic component 130 by an adhesive layer (not shown) to form the electronic device 10a′.

The material of the adhesive layer includes a resin film, an optical clear adhesive (OCA), a hot-melt adhesive, an optical pressure sensitive adhesive (PSA), or an optical pressure sensitive resin (OCR), but not limited thereto. In an embodiment, the electronic component 130 is, for example, a wire, an electrode, a resistor, an inductor, a capacitor, a transistor, a diode, a switch component, an amplifier, a processor, a controller, a thin film transistor, a touch component, a pressure sensing component, a microelectromechanical component, a feedback component, a display, a touch display component, single-chip module, multi-chip module, or other suitable electronic component. In some embodiments, the electronic component 130 may be an optical component or a component with a light filter layer, but not limited thereto. In an embodiment, the display may be an active matrix display or a passive matrix display, wherein the active matrix display may be an organic light emitting diode (OLED) display.

FIG. 1E is a schematic cross-sectional view of an electronic device according to another embodiment of the disclosure, wherein the electronic device 10b′-1 has a substrate 100 and an optical structure layer (OSL) OS.

Referring to FIG. 1E, the electronic device 10b′-1 is similar to the electronic device 10a′ in FIG. 1D, except that the electronic device 10b′-1 further includes the optical structure layer OS, wherein the optical structure layer OS is disposed on the second surface S2 of the substrate 100, and the optical structure layer OS is disposed between the substrate 100 and the electronic component 130. The optical structure layer OS may be adhered between the substrate 100 and the electronic component 130 through an adhesive or formed on the substrate 100 directly by wet coating or dry film-forming method. Details of the optical structure layer OS may be referred to the above embodiments and thus are not repeated herein.

FIG. 1F is a schematic cross-sectional view of an electronic device according to yet another embodiment of the disclosure, wherein the electronic device 10b′-2 has a substrate 100 and an optical structure layer (OSL) OS.

Referring to FIG. 1F, the electronic device 10b′-2 is similar to the electronic device 10b′-1 in FIG. 1E, except that the optical structure layer OS of the electronic device 10b′-2 is disposed on the first surface S1 of the substrate 100, and the optical structure layer OS is disposed between the substrate 100 and the auxiliary layer 110. The optical structure layer OS may be adhered between the substrate 100 and the auxiliary layer 110 through an adhesive or formed on the substrate 100 directly by wet coating or dry film-forming method. Details of the optical structure layer OS may be referred to the above embodiments and thus are not repeated herein.

FIG. 3A and FIG. 3B are schematic cross-sectional views of protective structures according to another embodiment of the disclosure. FIG. 3C and FIG. 3D are schematic cross-sectional views of electronic devices according to another embodiment of the disclosure.

Referring to FIG. 3A, the protective structure 20a is similar to the protective structure 10a in FIG. 1A, except that the protective structure 20a does not have the substrate 100. The protective structure 20a includes the auxiliary layer 110 and the hard coating layer 120. Referring to FIG. 3B, the protective structure 20a-1 is similar to the protective structure 20a in FIG. 3A, except that the protective structure 20a-1 further includes the optical structure layer OS, wherein the optical structure layer OS is disposed on the auxiliary layer 110, and the auxiliary layer 110 is disposed between the hard coating layer 120 and the optical structure layer OS. The optical structure layer OS may be adhered onto the auxiliary layer 110 through an adhesive or formed on the substrate 100 directly by wet coating or dry film-forming method. Details of the optical structure layer, OS may be referred to the description with regard to FIG. 1B and thus are not repeated herein.

Referring to FIG. 3C again, the electronic device 20a′ is similar to the electronic device 10a′ in FIG. 1D, except that the protective structure 20a of the electronic device 20a′ does not have the substrate 100. In an embodiment, the protective structure 20a may be formed directly on the electronic component 130. For example, the auxiliary layer 110 may be formed on the electronic component 130 by, for example, coating, printing, sputtering, or chemical vapor deposition, or the like, and the hard coating layer 120 is then formed by coating. The electronic device 20a′ is thus formed. The protective structure without the substrate may make the thickness thinner without affecting the function such as the anti-scratch function.

Next, referring to FIG. 3D, the electronic device 20a′-1 is similar to the electronic device 20a′ in FIG. 3C, except that the electronic device 20a′-1 further includes the optical structure layer OS, wherein the optical structure layer OS is disposed between the electronic component 130 and the auxiliary layer 110. The optical structure layer OS is adhered between the electronic component 130 and the auxiliary layer 110 through an adhesive or formed on the substrate 100 directly by wet coating or dry film-forming method, for example. Details of the optical structure layer OS may be referred to the description with regard to FIG. 1B and thus are not repeated herein.

In the embodiments of FIG. 3A to FIG. 3D, details of the components same as or similar to those in FIG. 1A to 1F may be referred to the description with regard to FIG. 1A to FIG. 1F and thus are not repeated herein. For example, the material, the thickness, the forming method, and the Young's modulus of the auxiliary layer 110 and the hard coating layer 120 as well as the electronic component 130 may be referred to the embodiments of FIG. 1A and FIG. 1D and thus are not repeated herein.

The protective structure of the embodiments of the disclosure may include the substrate 100 as shown in FIG. 1A or not include the substrate 100 as shown in FIG. 3A. Each of the following embodiments will be illustrated by a protective structure with a substrate. However, in these embodiments, the protective structure may also not include the substrate 100 but such illustration will not be repeated herein.

The protective structure of the embodiments of the disclosure may be combined with an electronic component into an electronic device as shown in FIG. 1B. Each of the following embodiments will be illustrated by a protective structure. However, in these embodiments, the protective structure may also be combined with an electronic component into an electronic device. Details of the electronic component may be referred to the electronic component 130 with regard to the embodiment of FIG. 1D and thus are not repeated herein.

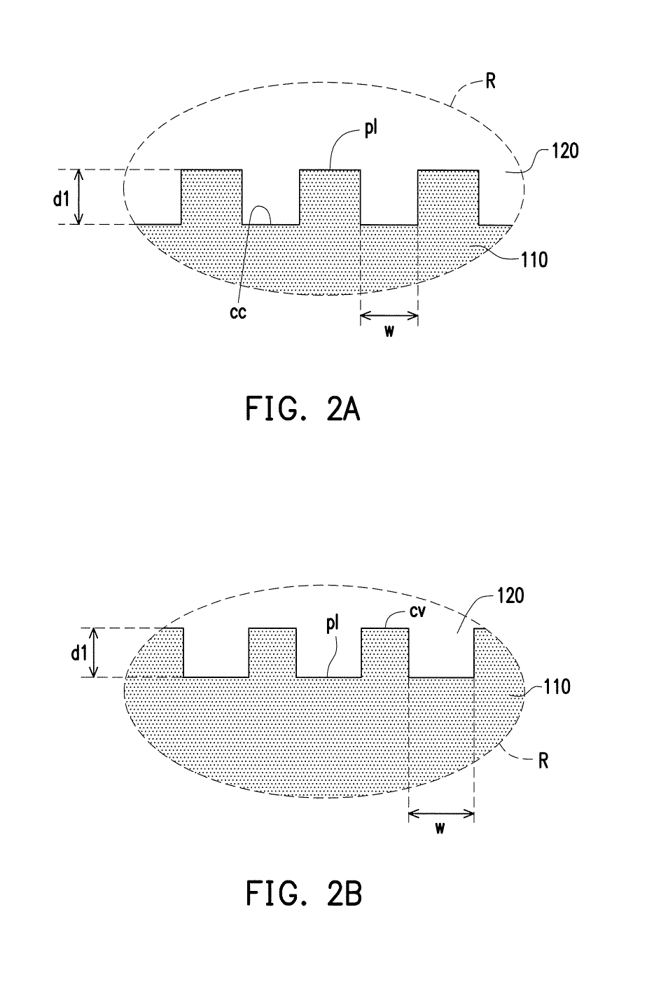

FIG. 4 is a schematic cross-sectional view of the protective structure according to another embodiment of the disclosure, in which the protective structure includes the substrate 100.

Referring to FIG. 4, the protective structure 10c is similar to the protective structure 10a in FIG. 1A, except that the auxiliary layer of the protective structure 10c is patterned, wherein the patterned auxiliary layer 110′ after being patterned has a plurality of first opening regions 110a which expose part of the substrate 100. Details of the components same as or similar to those in FIG. 1A may be referred to the embodiment of FIG. 1A and thus are not repeated herein. The hard coating layer 120 of the protective structure 10c is filled into each of the first opening regions 110a of the patterned auxiliary layer 110′ and contacts with the part of the substrate 100 which is exposed by the opening regions 110a, and a surface of the hard coating layer 120 which is away from the substrate 100 is substantially a flat surface.

In another embodiment which is not drawn, when the protective structure without the substrate 100 was applied in the electronic component, the plurality of first opening regions 110a expose part of the electronic component, and the hard coating layer 120 is filled into each of the first opening regions 110a of the patterned auxiliary layer 110′ and contacts directly with the part of the electronic component which is exposed by the opening regions 110a.

The method for patterning the auxiliary layer may be exposure and development or screen printing, or the like. After being patterned, the patterned auxiliary layer 110′ forms a plurality of patterns, wherein each two adjacent patterns have a gap spacing sp1 therebetween, and the gap spacing sp1 may be less than or equal to 5 μm. Patterning the auxiliary layer reduces the stress generated when the protective structure 10c is flexed or folded.

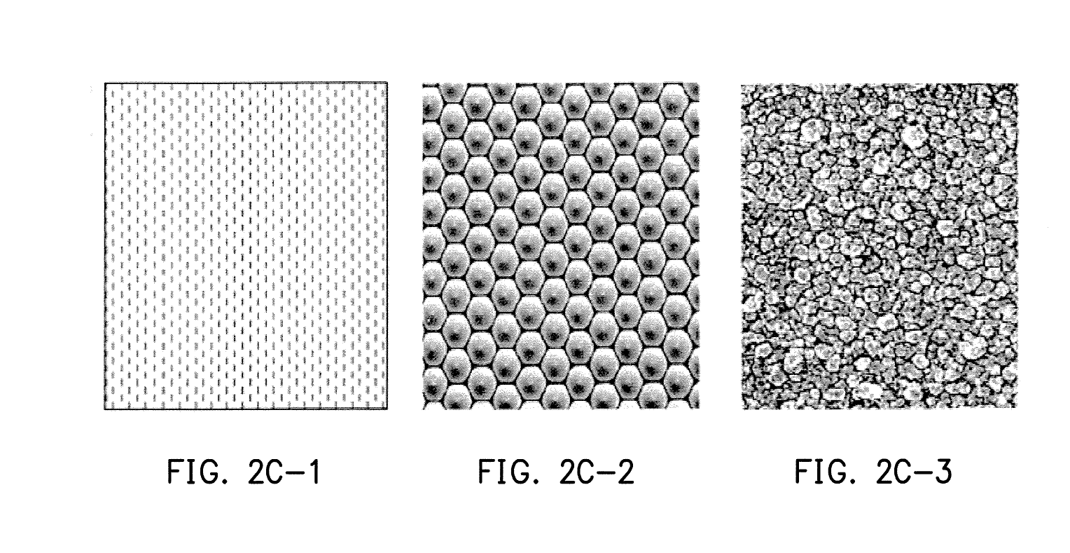

FIG. 5A to FIG. 5C are top views of patterned auxiliary layers according to embodiments of the disclosure. Referring to FIG. 5A, FIG. 5A shows a patterned auxiliary layer 110′ on the X-Y plane of the substrate 100 as shown in FIG. 4 in an embodiment, wherein the patterns of the structure of the patterned auxiliary layer 110′ may be connected with each other such as a mesh structure 110a′. As shown in FIG. 5A, the patterned auxiliary layer 110′ may have a stripe structure extending along the X and Y directions. The stripe structure of the patterned auxiliary layer 110′ may have a plurality of stripes and these strips of the patterned auxiliary layer 110′ intersect in the X and Y directions to form the mesh structure 110a′. In addition, the numbers of the strips of the auxiliary layer 110′ in the X and Y directions may be the same or different. Referring to FIG. 5B and FIG. 5C, the patterns of the structure of the patterned auxiliary layer 110′ may not be connected with each other. FIG. 5B shows the patterned auxiliary layer 110′ on the X-Y plane of the substrate 100 as shown in FIG. 4 in another embodiment. The patterned auxiliary layer 110′ may have a stripe structure 110b′ extending along one of the X and Y directions. The stripe structure of the patterned auxiliary layer 110′ may have a plurality of stripes which are parallel to each other. FIG. 5C shows the patterned auxiliary layer 110′ on the X-Y plane of the substrate 100 as shown in FIG. 4 in yet another embodiment. The patterned auxiliary layer 110′ may include a plurality of patterns that are not connected with each other. The plurality of patterns may have geometric shapes such as circular and polygonal (for example, hexagonal structure 110c′ shown in FIG. 5C) or other non-geometric shapes with a gap d2 between each two adjacent patterns of less than or equal to 5 μm. The above-mentioned patterned auxiliary layers are for illustration, and the patterns of the patterned auxiliary layers are not limited thereto.

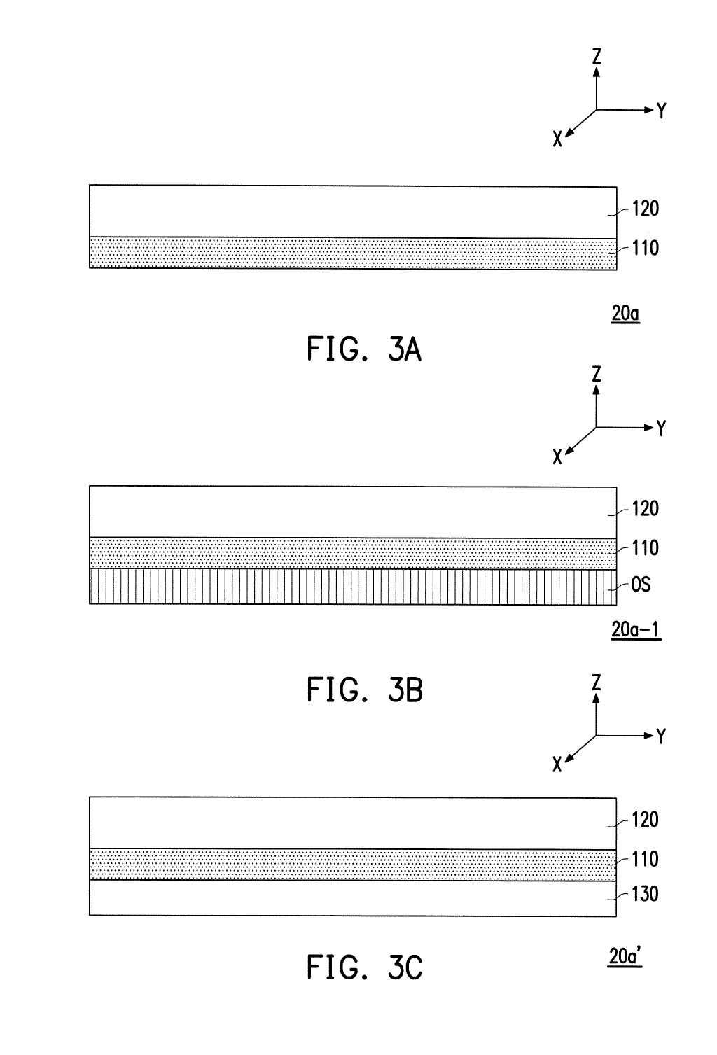

FIG. 6A is a schematic cross-sectional view of the protective structure according to another embodiment of the disclosure, in which the protective structure includes the substrate 100.

Referring to FIG. 6A, the protective structure 10d is similar to the protective structure 10a in FIG. 1A, except that the protective structure 10d includes an interlayer 140 disposed between the auxiliary layer 110 and the hard coating layer 120. Details of the components same as or similar to those in FIG. 1A may be referred to the embodiment of FIG. 1A and thus are not repeated herein. The interlayer 140 may include an organic material such as hexamethyldisilazane (HMDS), propylene glycol methyl ether acetate (PGMEA), acrylic resins, trimethoxysilane, polymethylmethacrylate (PMMA), methacryloxy propyl trimethoxyl silane, styrene copolymers (MS), cellulose acetate (CA), acrylic-based polymers, silane, or the like, or a combination of the forgoing, but not limited thereto. The interlayer 140 is formed by, for example, coating, printing or the like. The surface of the interlayer 140 near the hard coating layer 120 is substantially a flat surface, which increases the adhesion between the auxiliary layer 110 and the hard coating layer 120.

FIG. 6B is a schematic cross-sectional view of a protective structure according to another embodiment of the disclosure. Referring to FIG. 6B, the protective structure 10d-1 is similar to the protective structure 10d in FIG. 6A, except that the protective structure 10d-1 further includes an optical structure layer OS, wherein the optical structure layer OS is disposed on the substrate 100, and the substrate 100 is disposed between the optical structure layer OS and the auxiliary layer 110. The optical structure layer OS may be adhered onto the substrate 100 through an adhesive or formed on the substrate 100 directly by wet coating or dry film-forming method. Details of the optical structure layer OS may be referred to the description with regard to FIG. 1B and thus are not repeated herein.

FIG. 6C is a schematic cross-sectional view of a protective structure according to another embodiment of the disclosure. Referring to FIG. 6C, the protective structure 10d-2 is similar to the protective structure 10d-1 in FIG. 6B, except that the optical structure layer OS of the protective structure 10d-2 is disposed between the substrate 100 and the auxiliary layer 110. The optical structure layer OS may be adhered between the substrate 100 and the auxiliary layer 110 through an adhesive. Details of the optical structure layer OS may be referred to the description with regard to FIG. 1B and thus are not repeated herein.

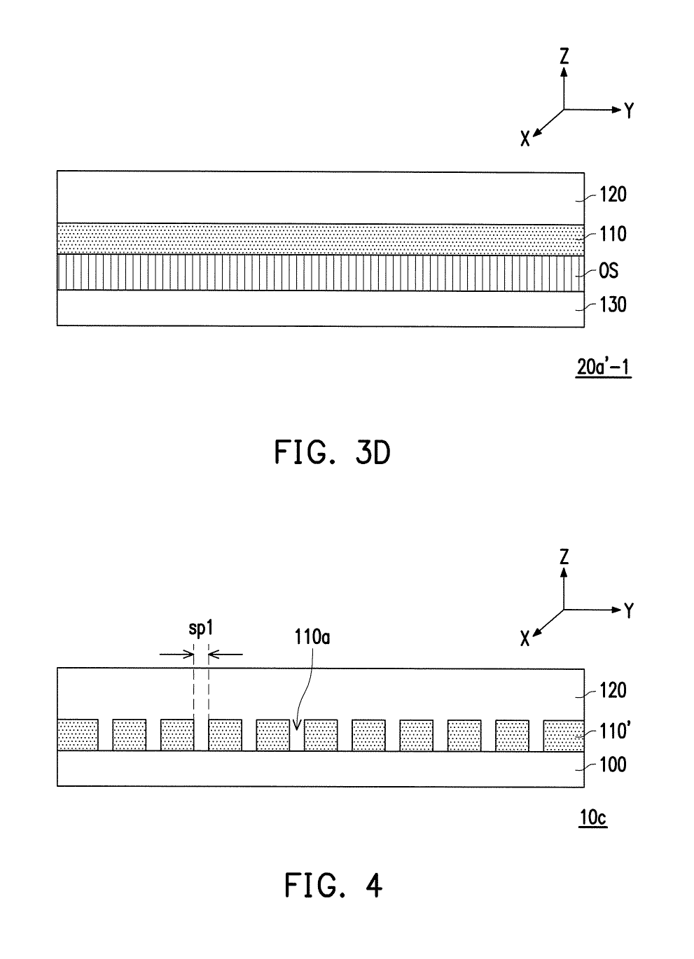

FIG. 7 is a schematic cross-sectional view of the protective structure according to another embodiment of the disclosure, in which the protective structure includes the substrate 100.

Referring to FIG. 7, the protective structure 10e is similar to the protective structure 10d in FIG. 6, except that the auxiliary layer of the protective structure 10e is patterned as the auxiliary layer shown in FIG. 4, and there is also an interlayer 140 disposed between the patterned auxiliary layer 110′ and the hard coating layer 120 shown in FIG. 6. Details of the same or similar components may be referred to the embodiments of FIG. 1A, FIG. 4 and FIG. 6 and thus are not repeated herein. The patterned auxiliary layer 110′ of the protective structure 10e has a plurality of first opening regions 110a. The interlayer 140 is filled into the plurality of the first opening regions 110a of the auxiliary layer 110′ and contacts with part of the substrate 100 which is exposed by the opening regions 110a, and a surface of the interlayer 140 which is away from the auxiliary layer 110′ is substantially a flat surface. The illustration for the top views of the exemplary patterned auxiliary layers 110′ may be referred to FIG. 5A to FIG. 5C.

In another embodiment, when the protective structure without the substrate 100 is applied in the electronic component, the plurality of first opening regions 110a expose part of the electronic component, the interlayer 140 is filled into each of the first opening regions 110a of the patterned auxiliary layer 110′ and contacts directly with the part of the electronic component which is exposed by the first opening regions 110a.

The method for patterning the auxiliary layer may be exposure and development or screen printing, or the like. After being patterned, the patterned auxiliary layer 110′ forms a plurality of patterns, wherein the gap spacing sp2 between each two adjacent patterns may be less than or equal to 5 μm. Patterning the auxiliary layer reduces the stress generated when the protective structure 10c is flexed or folded. The interlayer 140 increases the adhesion between the auxiliary layer 110 and the hard coating layer 120.

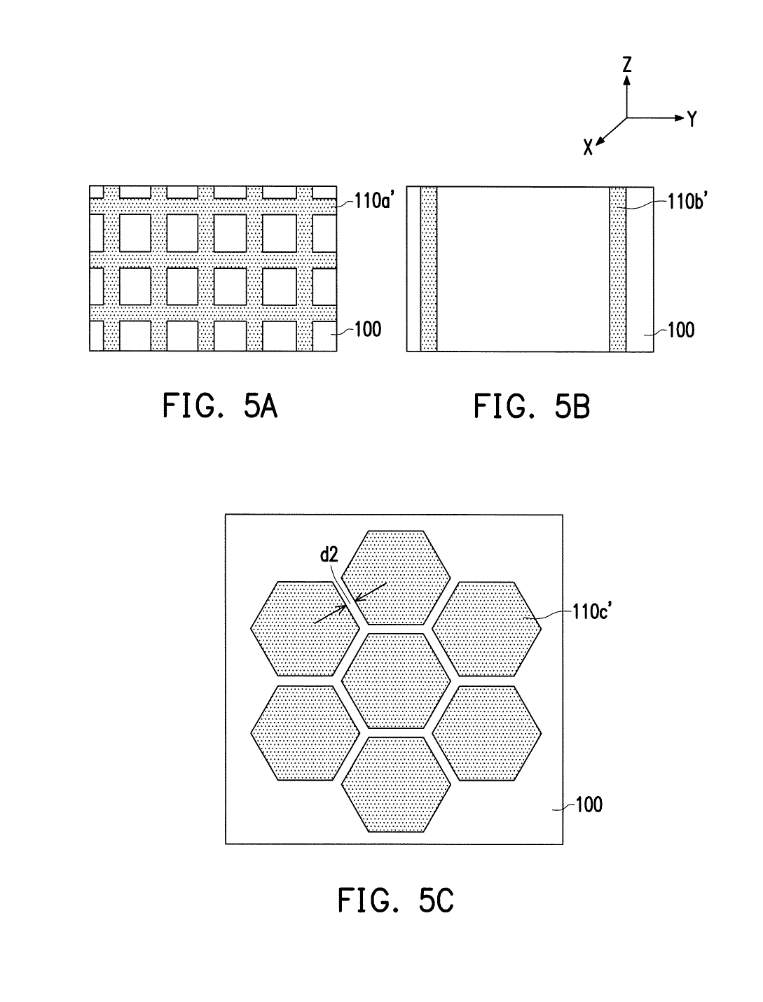

FIG. 8 is a schematic cross-sectional view of the protective structure according to another embodiment of the disclosure, in which the protective structure includes the substrate 100.

Referring to FIG. 8, the protective structure 10f is similar to the protective structure 10a in FIG. 1A, except that the hard coating layer of the protective structure 10f is a patterned hard coating layer 120′, and the auxiliary layer also covers the top and the sides of the patterned hard coating layer 120′ in addition to being formed between the substrate 100 and the hard coating layer 120′. Details of the same or similar components may be referred to the embodiment of FIG. 1A and thus are not repeated herein.

Still Referring to FIG. 8, in an embodiment, the auxiliary layer 110 is first formed on the substrate 100, and then the hard coating layer 120 is formed on the auxiliary layer 110. The method of forming the auxiliary layer 110 and the hard coating layer 120 may be referred to the above embodiments and thus are not repeated herein. Next, the hard coating layer 120 is subjected to a patterning process to form a patterned hard coating layer 120′. The patterned hard coating layer 120′ has a plurality of second opening regions 110b exposing a partial surface of the auxiliary layer 110. The method for patterning the hard coating layer 120 may be exposure and development or screen printing, or the like. Next, a first auxiliary layer 110″ is formed conformally to the patterned hard coating layer 120′ and the surface of the auxiliary layer 110 which is exposed by the patterned hard coating layer 120′. The method of forming the first auxiliary layer 110″ may be referred to the method of forming the auxiliary layer 110 and thus are not repeated herein. The first auxiliary layer 110″ covers the top and the sides of the patterned hard coating layer 120′ and covers the surface of the auxiliary layer 110 which is exposed by the patterned hard coating layer 120′. The thickness of the first auxiliary layer 110″ which covers above the patterned hard coating layer 120′ and covers the surface of the auxiliary layer 110 exposed by the patterned hard coating layer 120′ is, for example, about 0.8 μm.

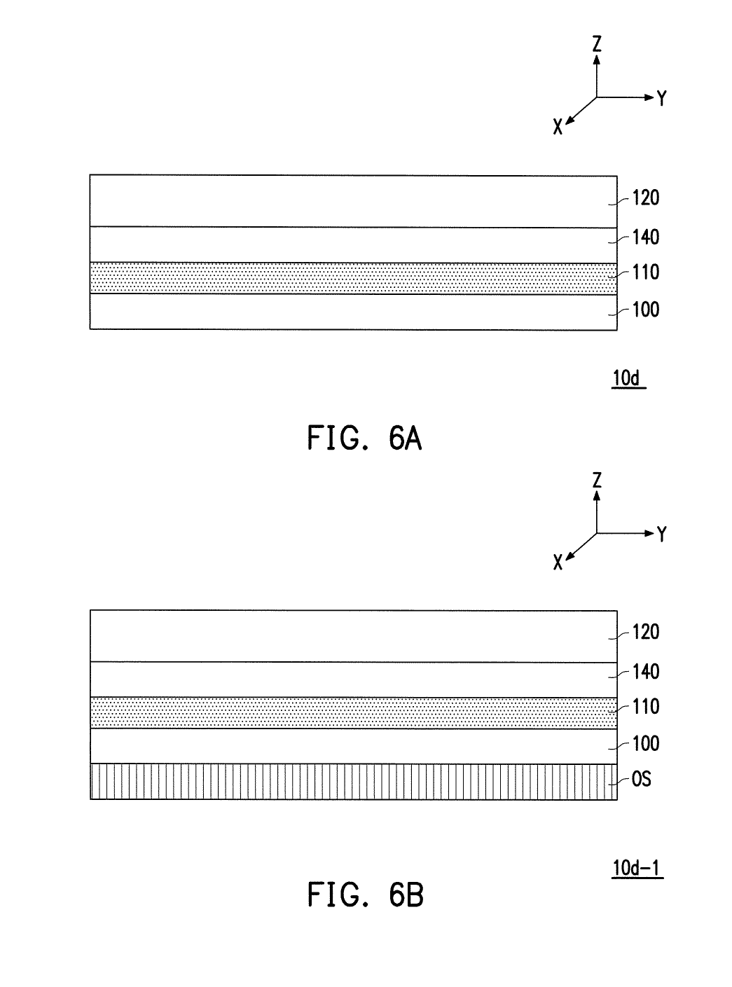

FIG. 9 is a schematic cross-sectional view of the protective structure according to another embodiment of the disclosure, in which the protective structure includes the substrate 100.

Referring to FIG. 9, the protective structure 10g is similar to the protective structure 10f in FIG. 8, except that the protective structure 10g includes an interlayer 140 disposed between the auxiliary layer 110 and the patterned hard coating layer 120′. Details of the same or similar components may be referred to the above embodiments and thus are not repeated herein. A partial surface of the interlayer 140 of the protective structure 10g is covered by the patterned hard coating layer 120′ and the other partial surface is covered by the first auxiliary layer 110″.

Still Referring to FIG. 9, in an embodiment, the auxiliary layer 110 is first formed on the substrate 100, the interlayer 140 is then Ruined on the auxiliary layer 110, and then the hard coating layer 120 is formed on the interlayer 140, wherein the auxiliary layer 110 is between the substrate 100 and the interlayer 140. The methods of forming the auxiliary layer 110, the interlayer 140, and the hard coating layer 120 may be referred to the above embodiments and thus are not repeated herein. Next, the hard coating layer 120 is subjected to a patterning process to form a patterned hard coating layer 120′. The patterned hard coating layer 120′ exposes a partial surface of the interlayer 140. The method for patterning the hard coating layer 120 may be exposure and development or screen printing, or the like. Next, a first auxiliary layer 110″ is formed conformally to the patterned hard coating layer 120′ and the surface of the interlayer 140 which is exposed by the patterned hard coating layer 120′. The method of forming the first auxiliary layer 110″ may be referred to the method of forming the auxiliary layer 110 and thus are not repeated herein. The first auxiliary layer 110″ covers the top and the sides of the patterned hard coating layer 120′ and covers the surface of the interlayer 140 which is exposed by the patterned hard coating layer 120′. The thickness of the first auxiliary layer 110″ which covers above the patterned hard coating layer 120′ and covers the surface of the interlayer 140 which is exposed by the patterned hard coating layer 120′ is, for example, about 0.8 μm.

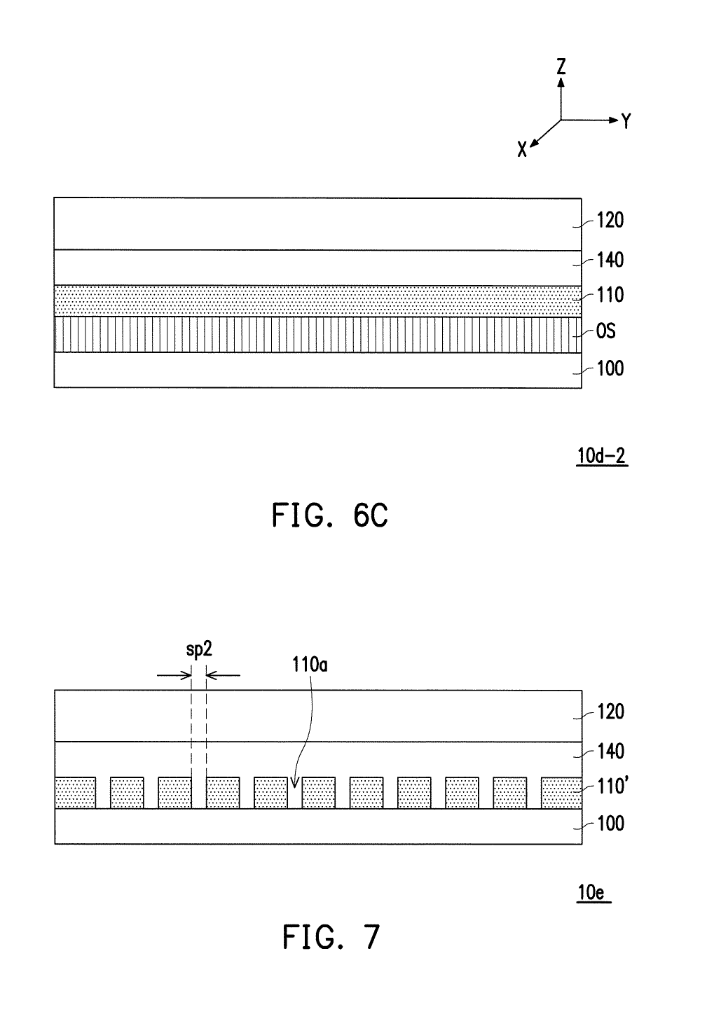

FIG. 10 is a schematic cross-sectional view of the protective structure according to another embodiment of the disclosure, in which the protective structure includes the substrate 100.

Referring to FIG. 10, the protective structure 10h is similar to the protective structure 10a in FIG. 1A, except that the auxiliary layer of the protective structure 10h is patterned. Details of the same or similar components and the method of forming the patterned auxiliary layer may be referred to the above embodiments and thus are not repeated herein. In this embodiment, a patterned auxiliary layer 110′ having a first portion 1101 and a second portion 1102 is formed after the auxiliary layer is patterned. The first portion 1101 is disposed on the first surface S1 of the substrate 100 and completely cover the first surface S1 of the substrate 100. The second portion 1102 is disposed on the first portion 1101 and is patterned. The patterned second portion 1102 has a plurality of third opening regions 110c which expose part of the first portion 1101 of the patterned auxiliary layer 110′. Details of the same or similar components may be referred to the embodiment of FIG. 1A and thus are not repeated herein. The hard coating layer 120 of the protective structure 10h is filled into the third opening regions 110c of the patterned auxiliary layer 110′ and contacts with the part of the first portion 1101 of the patterned auxiliary layer 110′ which is exposed by the third opening regions 110c. A surface of the hard coating layer 120 which is away from the substrate 100 is substantially a flat surface.

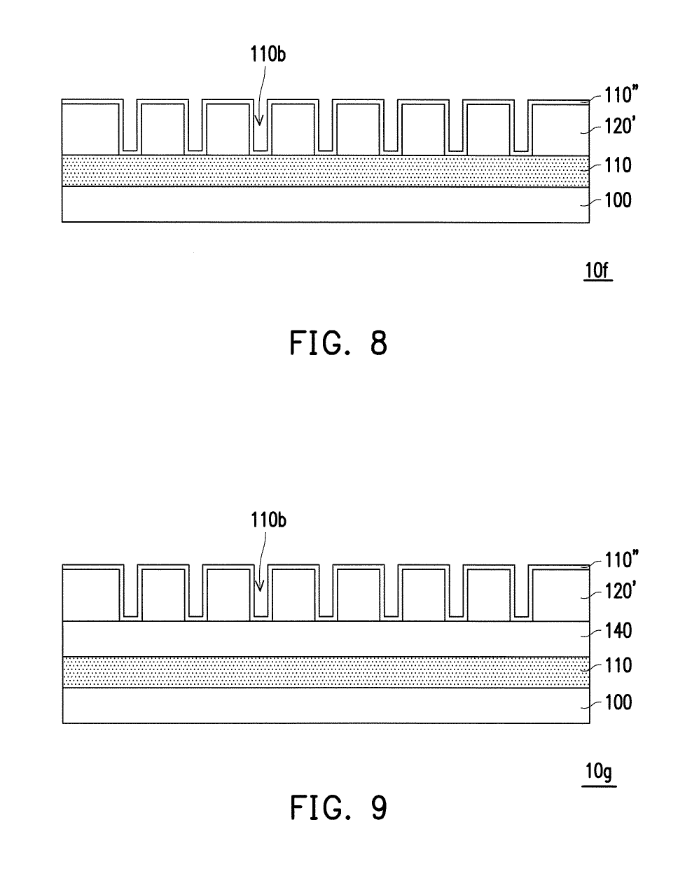

FIG. 11 is a schematic cross-sectional view of the protective structure according to another embodiment of the disclosure, in which the protective structure includes the substrate 100.

Referring to FIG. 11, the protective structure 10i is similar to the protective structure 10h in FIG. 10, except that the part of the first portion 1101 of the patterned auxiliary layer 110′ of the protective structure 10i which is exposed by the second portion 1102, and the top and the sides of the second portion 1102 of the auxiliary layer 110′ are all covered by the interlayer 140. Details of the same or similar components may be referred to the above embodiments and thus are not repeated herein. The hard coating layer 120 of the protective structure 10i is filled into the third opening regions 110c of the auxiliary layer 110′ and contacts with the interlayer 140. A surface of the hard coating layer 120 which is away from the substrate 100 is substantially a flat surface.

Referring to FIG. 11, the interlayer 140 of the protective structure 10i is formed conformally to the top and the sides of the second portion 1102 of the auxiliary layer 110′ and the first portion 1101 of the patterned auxiliary layer 110′ exposed by second portion 1102. The interlayer 140 is formed by, for example, coating, printing or the like. Forming the interlayer 140 conformally to the second portion 1102 of the auxiliary layer 110′ refers to that forming a layer of the interlayer 140 with a substantially equal thickness along the upper surface the second portion 1102 of the auxiliary layer 110′.

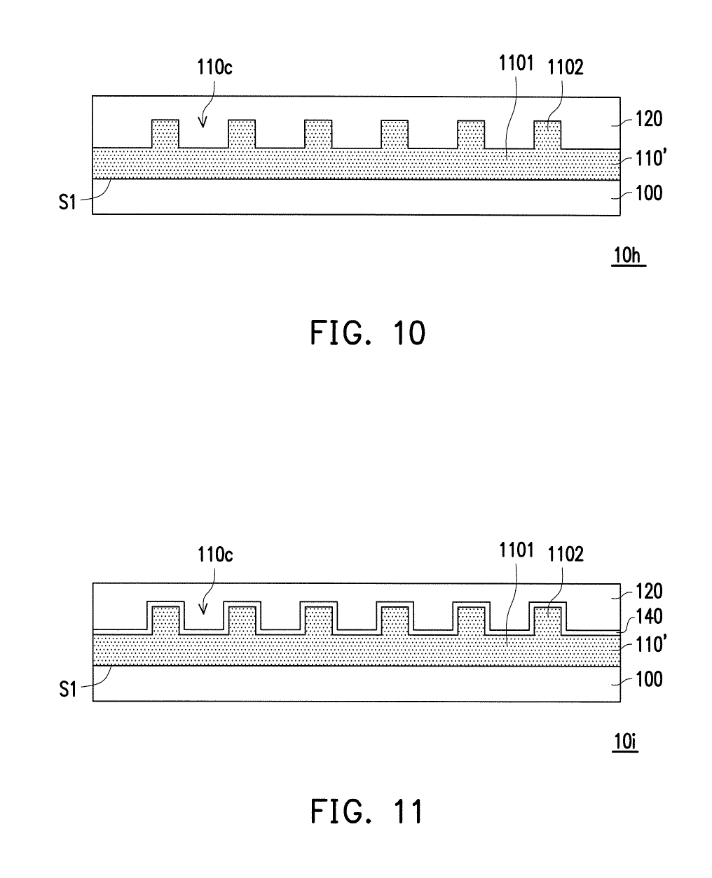

FIG. 12 is a schematic cross-sectional view of the protective structure according to another embodiment of the disclosure, in which the protective structure includes the substrate 100.

Referring to FIG. 12, the protective structure 10j in FIG. 12 includes two hard coating layers, i.e., a hard coating layer 120 and a first hard coating layer 1201. As shown in FIG. 12, the hard coating layer 120 as shown in the protective structure 10a of the embodiment of FIG. 1A is disposed on the substrate 100 and the auxiliary layer 110, and the first hard coating layer 1201 is disposed between the substrate 100 and the auxiliary layer 110. The materials of the hard coating layer 120 and the first hard coating layer 1201 may be referred to the embodiment of FIG. 1A and thus are not repeated herein. It should be noted that the materials of the hard coating 120 and the first hard coating 1201 may be the same or different, and the thickness may not be the same or different. In an embodiment, when the protective structure 10j is applied to a foldable device (e.g. a foldable display), the hard coating layer 120 and the first hard coating layer 1201 having the same Young's modulus may be used. In addition, the thickness of the hard coating layer 120 in the predetermined folding zone A1 is different from the thickness in the predetermined non-folding zone A2, and the thickness of the first hard coating layer 1201 in the predetermined folding zone A1 is different from the thickness in the predetermined non-folding zone A2. For example, the first hard coating layer 1201 is patterned to make the thickness of the first hard coating layer 1201 in the predetermined folding zone A1 greater than the thickness in the predetermined non-folding zone A2. The hard coating layer 120 is formed after the auxiliary layer 110 is formed conformally, and the surface of the hard coating layer 120 which is away from the substrate 100 is substantially a flat surface. In this case, the thickness of the hard coating layer 120 in the predetermined folding zone A1 is less than the thickness in the predetermined non-folding zone A2, and the thickness of the hard coating layer 120 is less than the thickness of the first hard coating layer 1201 in the predetermined folding zone A1. This structure reduces the stress that may be generated when the component is folded. In the other embodiments described above, the hard coating layer may also be patterned as described in this embodiment.

In another embodiment which is not drawn, similar to the protective structure 10j in FIG. 12, two hard coating layers are included, and the difference is that an interlayer is further formed between the auxiliary layer 110 and the hard coating layer 120. The material of the interlayer and the method of forming the patterned auxiliary layer may be referred to the above embodiments and thus are not repeated herein. It should be noted that the auxiliary layer 110 is formed conformally to the first hard coating layer 1201, and then the hard coating layer 120 is formed after the interlayer is formed conformally to the auxiliary layer 110, and the surface of the hard coating layer 120 which is away from the substrate is substantially a flat surface. In this case, the thickness of the hard coating layer 120 in the predetermined folding zone A1 is less than the thickness in the predetermined non-folding zone A2, and the thickness of the hard coating layer 120 is less than the thickness of the first hard coating layer 1201 in the predetermined folding zone A1. This structure reduces the stress that may be generated when the component is folded. In the other embodiments described above, the hard coating layer may also be patterned as described in this embodiment.

The effect of the protective structure of the embodiments of the disclosure is illustrated below by experiments and simulations.

### EXPERIMENTAL EXAMPLE

The surface hardness is tested for the structure of the electronic device 10a′ as shown in the embodiment of FIG. 1D, i.e., the structure in which the electronic component, the substrate, the auxiliary layer, and the hard coating layer are sequentially stacked (the surface to be tested is the surface of the hard coating layer which is away from the electronic component), wherein the substrate is polyimide (PI) with a thickness of 10 μm; the auxiliary layer is diamond-like carbon (DLC) with a thickness of 0.6 μm; the hard coating layer is a composite material of pentaerythritol tri(meth)acrylate and acrylate with a thickness of 25 μm (this electronic device structure is called the structure A). The actual measured surface hardness of this structure is 8˜9 H (pencil hardness). For comparison, the hardness test was also performed in the same way for the stack structure similar to structure A but without the auxiliary layer (this electronic device structure is called the structure B). The actual measured surface hardness of this structure is 5 H (pencil hardness). It may be seen that the presence of the auxiliary layer increases the hardness of the surface of the overall structure.

Further, the structure A and structure B are also separately subjected to the flexure test with the radius of curvature of 3 mm. Both of the structure A (with the auxiliary layer) and the structure B (without the auxiliary layer) are passed one hundred thousand times of the flexure test. In view of that, the presence of the auxiliary layer does not affect the flexibility of the structure.

### SIMULATION EXAMPLE

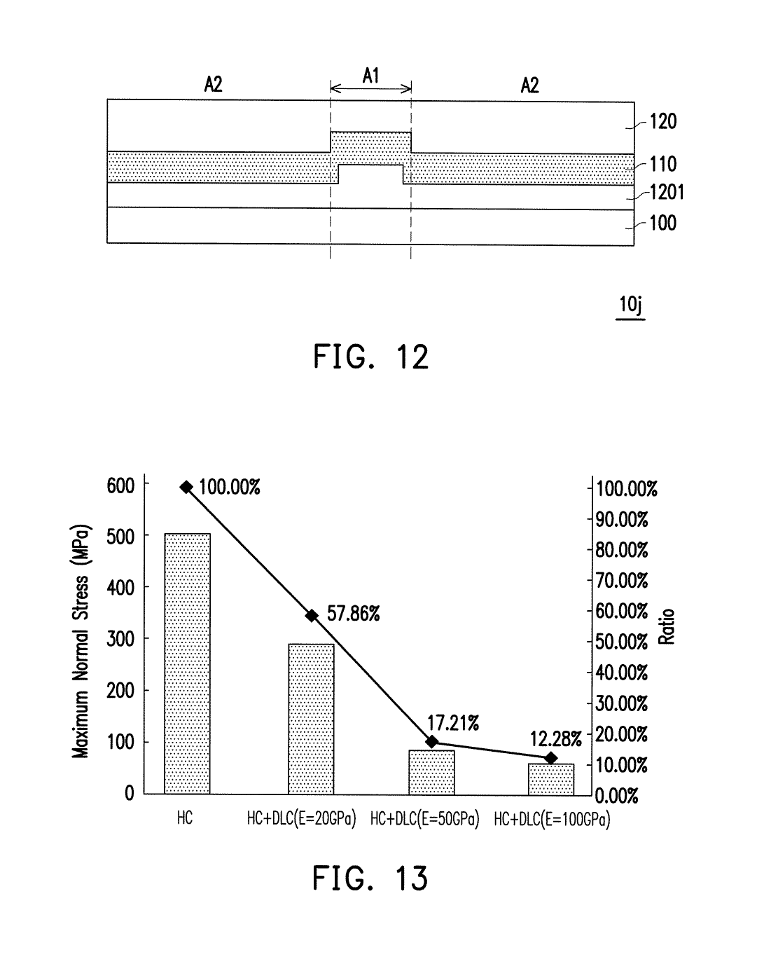

The simulation of the maximum normal stress on the surface between the substrate and the hard coating layer (HC) was performed on the structure A (with the auxiliary layer) and the structure B (without the auxiliary layer) of the above experimental examples. The simulation method employs a finite element method (FEM) and the simulation results are shown in FIG. 13.

Referring to FIG. 13, FIG. 13 is a diagram showing the simulation results of the different protective structures under the maximum normal stress. The horizontal axis represents the various simulated conditions. The leftmost one is the structure B i.e., the structure simply with the hard coating layer (HC) disposed above the substrate and without the auxiliary layer. Next structures are, in left-to-right sequence, a structure with the auxiliary layer [HC+DLC(E=20 GPa)], of which the material is diamond-like carbon (DLC) and the Young's modulus E is 20 GPa, a structure with the auxiliary layer [HC+DLC(E=50 GPa)], of which the material is diamond-like carbon and the Young's modulus E is 50 GPa, and a structure with the auxiliary layer [HC+DLC(E=100 GPa)], of which the material is diamond-like carbon and the Young's modulus E is 100 GPa, respectively. The left vertical axis represents the maximum normal stress, the right vertical axis represents the ratio of the maximum normal stress. Referring to the bar graph of FIG. 13, the maximum normal stresses of the various structures are shown. Referring to the left vertical axis (in MPa), the leftmost strip is the maximum normal stress of the structure B, and the value is 509.43 MPa. The next values are, in left-to-right sequence, 294.75 MPa (the auxiliary layer is diamond-like carbon with the Young's modulus of 20 GPa, HC+DLC(E=20 GPa)), 87.69 MPa (the auxiliary layer is diamond-like carbon with the Young's modulus of 50 GPa, HC+DLC(E=50 GPa)), and 62.55 MPa (the auxiliary layer is diamond-like carbon with the Young's modulus of 100 GPa, HC+DLC(E=100 GPa)), respectively. Then, referring to the line graph in FIG. 13, each node represents the ratio of the maximum normal stress of each structure to the maximum normal stress of the structure B and from left to right the ratio are 100%, 57.86%, 17.21% and 12.28%, respectively. It may be seen from the above simulation results that the maximum normal stress drops greater than 30% after the auxiliary layer is disposed, and the scratch resistance of the electronic device is improved.

It may be seen from the above embodiments that the protective structures of the disclosure may be formed on or attached to an electronic component (e.g., a flexible electronic component) to prevent the electronic component from being scratched by an external force and increase the service life and reliability of the electronic device. In addition, the electronic device of the embodiment of the disclosure includes an electronic component and a protective structure, and the protective structure may prevent the electronic component from being scratched by an external force and thereby increasing the service life and reliability of an electronic device.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A protective structure, comprising:
a substrate;
an auxiliary layer disposed on the substrate; and
a hard coating layer disposed on the auxiliary layer, wherein the auxiliary layer is disposed between the substrate and the hard coating layer, and the Young's modulus of the auxiliary layer is greater than the Young's modulus of the hard coating layer, and the Young's modulus of the hard coating layer is greater than the Young's modulus of the substrate.

2. The protective structure according to claim 1, wherein the Young's modulus of the auxiliary layer is between 15 and 100 GPa, the Young's modulus of the hard coating layer is between 10 and 30 GPa, and the Young's modulus of the substrate is between 1 and 20 GPa.

3. The protective structure according to claim 2, wherein the thickness of the auxiliary layer is between 0.1 and 30 μm, the thickness of the hard coating layer is between 5 and 35 μm, and the thickness of the substrate is between 5 and 50 μm.

4. The protective structure according to claim 3, further comprises an optical structure layer, wherein the optical structure layer is disposed on the substrate, the substrate is disposed between the optical structure layer and the auxiliary layer, and the optical structure layer has a Young's modulus of 1 to 20 GPa and a thickness of 0.5 to 20 μm.

5. The protective structure according to claim 3, further comprises an optical structure layer, wherein the optical structure layer is disposed between the substrate and the auxiliary layer, and the optical structure layer has a Young's modulus of 1 to 20 GPa and a thickness of 0.5 to 20 μm.

6. The protective structure according to claim 1, wherein the auxiliary layer comprises an inorganic material, an organic material or a composite material of an organic material and an inorganic material, wherein the inorganic material comprises diamond-like carbon, silicon nitride, silicon oxide, silicon oxynitride, aluminum oxide, aluminum titanium dioxide, sapphire coating, titanium oxynitride, or polysilazane.

7. The protective structure according to claim 6, wherein a surface of the auxiliary layer which is near the hard coating layer is a non-continuous surface, and the non-continuous surface has a surface structure with micro gaps of less than 1 μm.

8. The protective structure according to claim 6, wherein the hard coating layer comprises pentaerythritol tri(meth)acrylate, an acrylate material, or a combination of the forgoing materials.

9. The protective structure according to claim 1, wherein the auxiliary layer is a patterned auxiliary layer having a plurality of first opening regions, and the hard coating layer is filled into the plurality of first opening regions of the patterned auxiliary layer.

10. The protective structure according to claim 1, further comprising an interlayer, wherein the interlayer is disposed between the auxiliary layer and the hard coating layer.

11. The protective structure according to claim 10, wherein the auxiliary layer is a patterned auxiliary layer having a plurality of first opening regions, and the interlayer is filled into the plurality of first opening regions of the patterned auxiliary layer.

12. The protective structure according to claim 1, wherein the hard coating layer is a patterned hard coating layer having a plurality of second opening regions, and the protective structure further comprising a first auxiliary layer, and the first auxiliary layer covers a top and sides of the patterned hard coating layer and covers a partial surface of the auxiliary layer which is exposed by the plurality of second opening regions.

13. The protective structure according to claim 1, wherein the auxiliary layer is a patterned auxiliary layer comprising a first portion and a second portion, wherein the second portion has a plurality of third opening regions exposing a partial surface of the first portion, and the hard coating layer is filled into the plurality of third opening regions.

14. The protective structure according to claim 13, further comprising an interlayer, wherein the interlayer covers a top and sides of the second portion, and covers a partial surface of the first portion which is exposed by the plurality of third opening regions, and the hard coating layer covers the interlayer.

15. The protective structure according to claim 1, further comprising a first hard coating layer disposed between the substrate and the auxiliary layer, wherein the thickness of the first hard coating layer in a predetermined folding zone is greater than the thickness in a predetermined non-folding zone, and the thickness of the hard coating layer in the predetermined folding zone is less than the thickness in the predetermined non-folding zone.

16. An electronic device, comprising:
an electronic component; and
a protective structure disposed on the electronic component, wherein the protective structure comprises at least a hard coating layer and an auxiliary layer, wherein the auxiliary layer is disposed between the electronic component and the hard coating layer, and wherein the Young's modulus of the auxiliary layer is greater than the Young's modulus of the hard coating layer.

17. The electronic device according to claim 16, further comprising an optical structure layer, wherein the optical structure layer is disposed between the electronic component and the auxiliary layer, and the Young's modulus of the optical structure layer is between 1 and 20 GPa.

18. A protective structure adapted for an electronic component, comprising:
a hard coating layer disposed on the electronic component; and
an auxiliary layer disposed between the electronic component and the hard coating layer, wherein the Young's modulus of the auxiliary layer is greater than the Young's modulus of the hard coating layer.

19. The protective structure according to claim 18, wherein the Young's modulus of the auxiliary layer is between 15 and 100 GPa and the Young's modulus of the hard coating layer is between 10 and 30 GPa.

20. The protective structure according to claim 19, wherein a thickness of the auxiliary layer is between 0.1 and 30 μm and a thickness of the hard coating layer is between 5 and 35 μm.

21. The electronic device according to claim 20, further comprising an optical structure layer, wherein the optical structure layer is disposed on the auxiliary layer, and the Young's modulus of the optical structure layer is between 1 and 20 GPa.

22. The protective structure according to claim 18, wherein
the auxiliary layer comprises an inorganic material, an organic material or a composite material of an organic material and an inorganic material, wherein the inorganic material comprises diamond-like carbon, silicon nitride, silicon oxide, silicon oxynitride, aluminum oxide, aluminum titanium dioxide, sapphire coating, titanium oxynitride, or polysilazane.

23. The protective structure according to claim 22, wherein a surface of the auxiliary layer which is near the hard coating layer is a non-continuous surface, and the non-continuous surface has a surface structure with micro gaps of less than 1 μm.

24. The protective structure according to claim 22, wherein the hard coating layer comprises pentaerythritol tri(meth)acrylate, an acrylate material, or a combination thereof.
